(19) United States
(12) Patent Application Publication
(10) Pub. No.: US 2004/0201080 A1
(43) Pub. Date: Oct. 14, 2004

(54) Leadless leadframe electronic package and IR transceiver incorporating same

(76) Inventors: Suresh Basoor, Singapore (SG); Chye Lin Toh, Singapore (SG); Kah Phang Loh, Singapore (SG)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/409,265

(22) Filed: Apr. 8, 2003

(51) Int. Cl. H01L 23/495

(52) U.S. Cl. 257/666

(57) ABSTRACT

A leadless lead frame electronic package (LLP) includes a lead frame of thermally-and-electrically conductive material encapsulated in an encapsulation of electrically-insulating material to define a planar mounting surface including an exposed web of encapsulation forming a portion of the planar mounting surface. The lead frame includes parallel internal and external planar surfaces with the external surface defining a recessed C-shaped channel therein for receiving the web of encapsulation. The external planar surface of the lead frame remains exposed through the encapsulation adjacent the web, with the web and the external planar surface adjacent the web extending generally co-planar with the mounting surface. The encapsulation is a transparent material forming a lens. The internal surface of the lead frame may include an attachment site for an optical component, with the lens being aligned with the attachment site for the optical component.

### TECHNICAL FIELD OF THE INVENTION

This invention relates to packaging of electronic components, and more particularly to packaging an infrared transceiver.

### BACKGROUND OF THE INVENTION

In many types of electronic equipment, including computer and telephone networks transmitting voice and data signals, signals are transmitted by light pulses traveling through fiber optic cables. At one or both ends of such cables, a device known as an optical transceiver is used for converting the light pulses into electrical signals that can be communicated to electrical components. Such optical transceivers, are sometimes referred to as opto-couplers, or infrared (IR) transceivers where the light pulses are formed from infrared light.

Optical transceivers are also sometimes used without fiber optic cables in electrical circuits to provide electrical isolation between various parts of the electronic circuit, or for wireless data transfer over short distances between electronic devices such as a computer and a personal data assistant (PDA).

A typical optical transceiver includes a light emitting diode (LED) for generating light pulses, and a detector for receiving light pulses from electrical signals, and for converting the received light pulses into electrical signals. The optical transceiver also typically includes a pair of lenses, one associated with the LED and one associated with the detector, for directing light from the LED into the fiber optic cable, and from the cable onto the detector.

It is highly desirable that the optical transceiver be small in physical size. It is also necessary to provide some means for removing heat generated within the optical transceiver during operation. The LED generates heat during operation. As optical transceivers are made physically smaller, the problem of removing heat becomes more difficult, necessitating that some sort of heat exchanging mechanism be provided for dissipating the heat.

FIG. 1 shows a prior optical transceiver 10, having an LED 12 and a detector 14 mounted on a printed circuit board (PCB) 16, and attached to electrical traces (not shown) on an upper surface 18 of the PCB 16. A series of grommet-like connections, known as vias 20, pass through the PCB 16, and have a bottom end 22 (as depicted) that is exposed for attachment of the transceiver 10 to a circuit board of an electronic device. The vias 20 are filled with solder. The LED 12 and detector 14 are encapsulated in an encapsulation 24, forming a first and a second lens 26, 28 covering the LED 12 and detector 14 respectively, for directing light to and from the transceiver 110. The edges of the transceiver 10 are trimmed after the encapsulation 24 is in place, by a process such as sawing. The vias 20 are positioned along the edge of the transceiver 10 such that, as the transceiver is trimmed to final size, half of each via 20 is cut away, leaving the remaining half of each via 20 embedded in the finished edge of the transceiver 10, and exposed for making electrical connections.

While this construction works well in some applications, additional improvements are desirable. Although the finished transceiver 10 is very small, approximately 2.5 mm high×8.5 mm long×3 mm wide, it is desirable to further reduce its size. The transceiver 10, shown in FIG. 1, includes a substantial number of parts. It is desirable to reduce the number of parts and operations required for fabrication the transceiver 10. Having the LED 12 and the detector 14 mounted on the PCB 16 also inhibits the removal of heat generated by the LED 12 during operation of the transceiver 10.

It would be desirable to utilize a relatively new type of electronic package technology, known as a Leadless Lead frame Package (LLP) for packaging an improved optical transciever. In an LLP, a metal lead frame substrate is formed by a process such as chemical etching from a thin sheet of metal (typically copper). The LLP includes at least one cut-out extending between parallel internal and external surfaces of the lead frame, with the cut-out forming a die-attach pad and one or more leadless connection pads. A die is mounted on the die-attach surface, and wire bonds or other types of electrical connections are made between the die and the internal surfaces of the connection pads. An electrically insulating encapsulating material is then molded around the lead frame, die and wire bonds. After the encapsulation is cured, the LLP is trimmed to final shape. U.S. Pat. Nos. 6,143,981, to Glenn, and 6,372,539 B1, to Bayan, et al, disclose LLP electronic packages.

An LLP differs from other types of lead frame based packages, in that there are no metal leads extending from the finished LLP for insertion into or attachment to pads on a printed wiring board (PWB). In an LLP, the connection pads are used for forming a leadless connection by applying a ball of solder crème or paste between the connection pads of the LLP and mating pads on the PWB, and subjecting the PWB to a process such as solder reflow. U.S. Pat. No. 4,927,697, to Hill, describes a method for attaching and LLP to a PWB.

One difficulty encountered in prior LLP packages, however, is that the die attach pads and connection pads separate from, and sometimes even fall out of the encapsulation. It is desirable that an improved LLP package include provisions for precluding separation and/or loss of the die attach pads.

What is needed is an improved optical transceiver, preferably using an LLP construction, and an apparatus and method for mounting such an improved transceiver on a printed wiring board.

### SUMMARY OF THE INVENTION

The invention provides an improved leadless electronic package (LLP) for mounting a wide variety of electronic dies, including optical component dies, on a printed wiring board using common high-production methods, such as solder reflow.

In one form of the invention a leadless lead frame electronic package (LLP) includes a lead frame of thermally-and-electrically conductive material encapsulated in an encapsulation of electrically-insulating material to define a planar mounting surface including an exposed web of encapsulation forming a portion of the planar mounting surface. The lead frame includes parallel internal and external planar surfaces with the external surface defining a recessed C-shaped channel therein for receiving the web of encapsulation. The external planar surface of the lead frame remains exposed through the encapsulation adjacent the web, with the web and the external planar surface adjacent the web extending generally co-planar with the mounting surface.

The encapsulation may be a transparent material forming a lens. The internal surface of the lead frame may include an attachment site for an optical component, with the lens being aligned with the attachment site for the optical component.

The lead frame may include at least one cut-out extending from the internal surface to the external surface to define a die-attach pad and at least one connection pad electrically isolated from the die-attach pad. The die attach pad and the connection pads extend through the encapsulation, with a portion of the external surfaces thereof exposed and generally coplanar with the encapsulation, and with a portion of the internal surfaces thereof respectively defining a die-attach surface and a bond-connection surface. The encapsulation may extend through a portion of the at least one cut-out in the lead frame. The external surface of the die attach pad includes the recessed C-shaped channel containing the web of encapsulation. The external surface of at least one of the connection pads may also include a second recessed area containing a second web of encapsulation.

The invention may also take the form of an electronic module including one or more electronic dice attached to the internal planar surface of the lead frame of a package as described above. The first optical component may be a light emitting diode (LED) and the second optical component a detector in the form of a photodiode, to thereby form an optical transceiver module.

The invention may also take the form of a method for attaching an electrical module, according to the invention, to a circuit board by thermally connecting at least part of the exposed external surface of the die-attach pad adjacent the web to the circuit board. Common production processes, including soldering, may be used for thermally connecting the part of the exposed external surface of the die-attach pad adjacent the web to the circuit board.

The foregoing and other features and advantages of the invention are apparent from the following detailed description of exemplary embodiments, read in conjunction with the accompanying drawing. The detailed description and drawing are merely illustrative of the invention rather than limiting, the scope of the invention being defined by the appended claims and equivalents thereof.

### BRIEF DESCRIPTION OF THE DRAWINGS

FIG. 1 is an enlarged side view of a prior optical transceiver;

FIG. 2 is an enlarged perspective view of an exemplary embodiment of an optical transceiver, according to the invention;

FIG. 3 is an enlarged cross section of the embodiment of FIG. 2;

FIG. 4 is an enlarged bottom view of a lead frame blank used to form the lead frame of the exemplary embodiment of the package of FIGS. 2 and 3;

FIG. 5 is an enlarged top view of the lead frame blank of FIG. 4, with electronic component dice and wire bonds attached to the lead frame;

FIG. 6 is an enlarged perspective view of the internal components of the module of FIGS. 2 and 3;

FIG. 7 is an enlarged bottom view of the module of FIGS. 2 and 3; and

FIG. 8 is an enlarged side view of the module of FIGS. 2 and 3.

### DETAILED DESCRIPTION

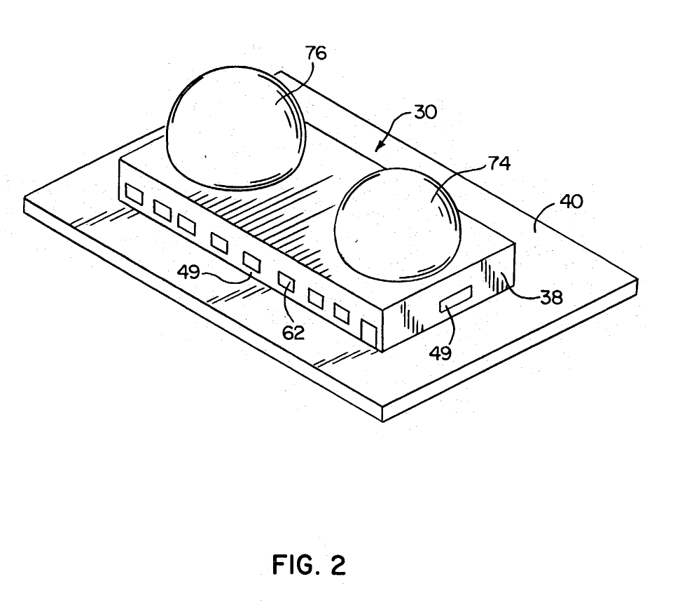

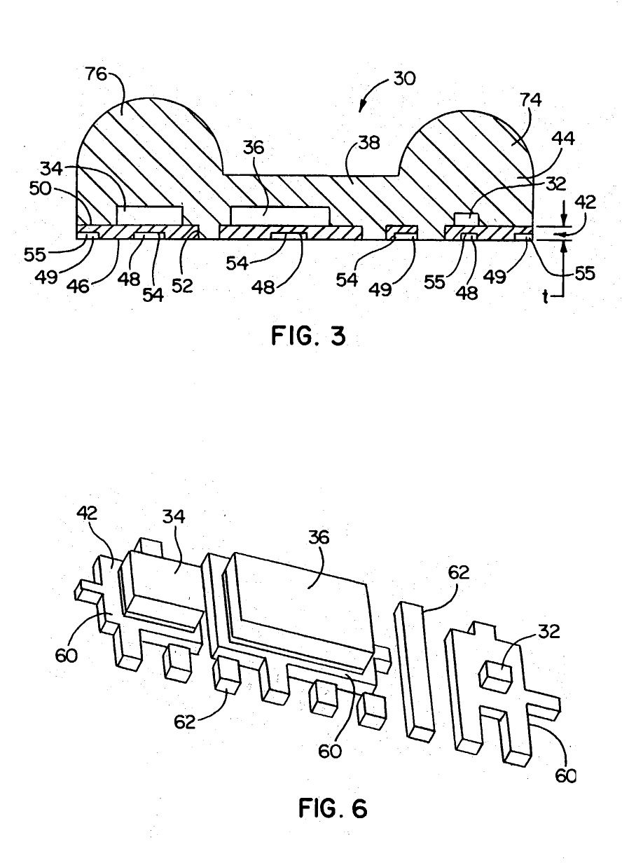

FIGS. 2 through 8 show an exemplary embodiment of an optical transceiver module 30, according to the invention. As shown, in FIG. 3, the transceiver module 30 includes a light emitting diode (LED) 32, a detector 34, and a signal processor 36 mounted in an electronic package 38. The electronic package 38 is a leadless, lead frame based, flat package (LLP) that can be soldered directly to a circuit board 40, as shown in FIG. 2.

As shown in FIGS. 3-6, the electronic package 38 includes a lead frame 42 of a thermally and electrically conductive material such as copper. The lead frame 42 is encapsulated in an encapsulation 44 of electrically insulating material defining a planar mounting surface 46 of the package 38, including several exposed webs 48, 49 of the encapsulation 44 forming a portion of the planar mounting surface 46.

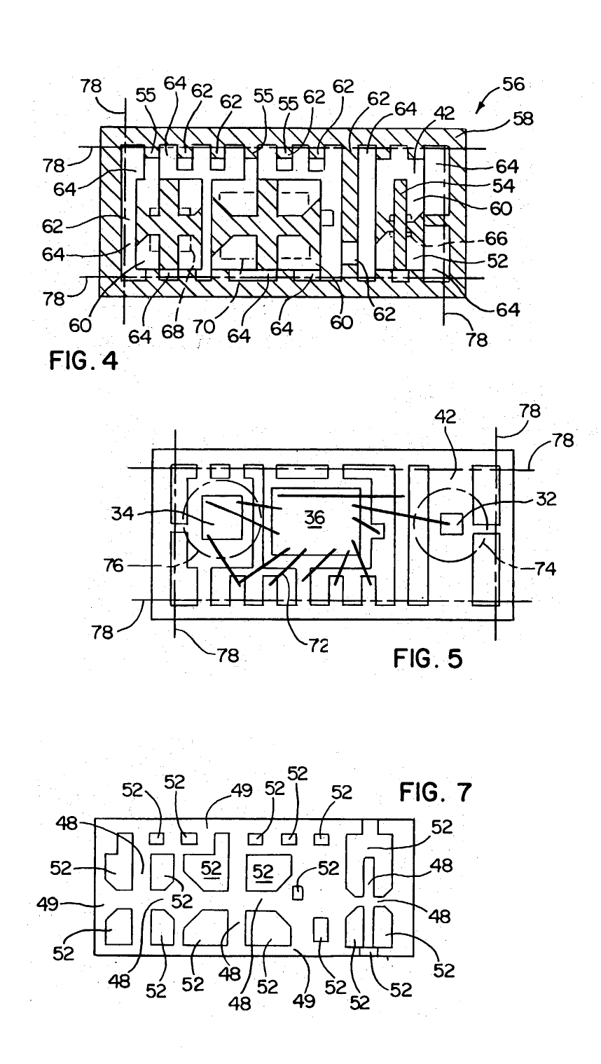

The lead frame 42 has substantially parallel internal and external planar surfaces 50, 52, separated from one another by a thickness t of the lead frame 42. The external surface 52 defines recessed C-shaped channels 54 and recessed portions 55, as shown in FIG. 2, and in FIG. 4 by dense cross-hatched lines, for receiving the webs 48, 49 of encapsulation 44. The external planar surface 52 of the lead frame 42 remains exposed through the encapsulation 44 adjacent the webs 48. The webs 48, 49 and the external planar surface 52 adjacent the webs 48, 49 extend generally co-planar with the mounting surface 46, as shown in FIG. 3.

The package 38 is fabricated by forming a lead frame blank 56, as shown in FIG. 4, having an outer rim 58 interconnecting three die pads 60, and a plurality of leadless connection pads 62, of the lead frame 42. The lead frame blank 56 includes cutouts 64 extending through the thickness t of the lead frame 42 from the internal to the external surfaces 50, 52. The cutouts 64 define the peripheries of the three die-attach pads 60 and the plurality of connection pads 62, that become electrically isolated from the die-attach pads 62, when the rim 58 is removed. Each of the connection pads 62 and the die-attach pads 60 retains a portion of the internal and external surfaces 50, 52 of the lead frame 44.

FIG. 4 is a bottom view of the lead frame blank 56, showing the recessed C-shaped channels 54 and the recessed areas 55 in the external surface 52 of the lead frame 42. Also indicated by dashed lines on FIG. 4, are a first, second and third die attach site 66, 68, 70 on the internal surface of the lead frame 42. The lead frame blank 56 can be formed by a variety of methods, including machining, stamping, casting, and chemical etching.

After the lead frame blank 56 of the exemplary embodiment is formed, the blank is inverted, as shown in FIG. 5, and the LED 32, detector 34, and signal processor 36 dice are attached to the internal surface 50 of the lead frame 42 at the first second and third die attach sites 66, 68, 70 respectively. A number of wire bonds 72 are attached between the LED 32, detector 34, and signal processor 36 dies, and connection sites on the die attach pads 60 and connection pads 62, to provide interconnection of all of the internal components of the module 30.

The wired lead frame blank 56 is then encapsulated in the encapsulation 44. In the exemplary embodiment of the module 30, an optically clear material, such as polycarbonate is used for forming the encapsulation 44, and the encapsulation 44 is molded in such a manner that a first and a second lens 74, 76 are formed in the encapsulation 44. The first lens 74 is aligned with the first die attach site 66 for collimating light emitted by the LED 32 into a beam of light. The second lens 76 is aligned with the second die attach site 68 for focusing light impinging on the second lens 76 onto the detector 34.

The rim 56 and any portion of the encapsulation 44 extending beyond the lead frame 42 is then cut away by sawing or otherwise cutting the package 38 along cutting lines 78, to produce the final package 38 as shown in FIGS. 2, 3 and 7. To facilitate high volume production, the lead frames 42 of a number of packages 30 may be joined together by shared rims 58 to form a common lead frame blank 56. The common lead frame 56 is encapsulated as a unit and cut apart to form separate packages 30 after being encapsulated. Forming the package 30 in this manner greatly reduces the amount of labor that would be required to individually form a large number of packages 30.

FIG. 6 shows the various parts of the lead frame 42 after the rim 56 is trimmed away, with the LED 32, detector 34, and signal processor 36 dies attached to the die attach pads 60, and the encapsulation and wire bonds omitted for purposes of clarity of illustration. As shown in FIGS. 2 and 7 the encapsulation 44 extends through the cutouts 64, around the peripheries of the die-attach and connection pads 60, 62, and fills the C-shaped channels 54 and the recesses 55 in the external surface 56 of the package 38 to form the webs 48, 49. FIG. 7 is a bottom view of the finished module 30, showing the webs 48, 49 and the exposed areas of the external surface 52 of the lead frame 42 adjacent the webs 48, 49.

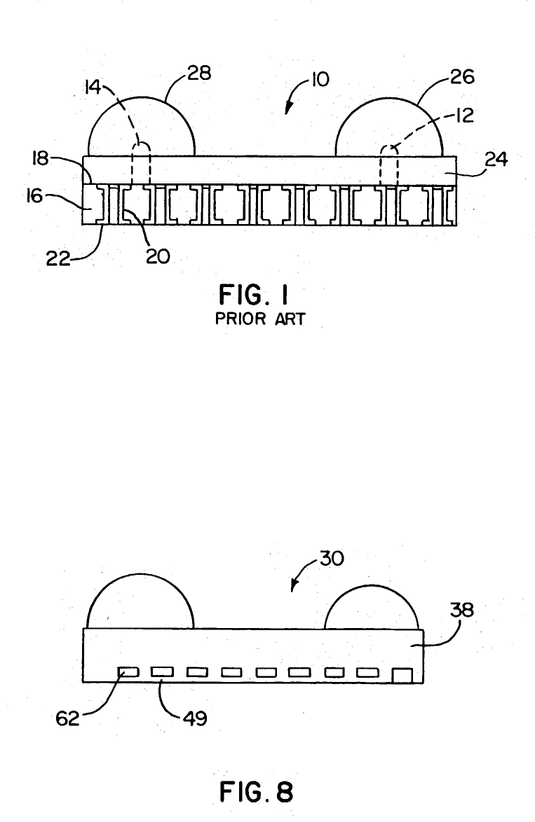

As will be appreciated by examining FIGS. 2, 3, 4, 7 and 8, the exemplary embodiment of the LLP package 38 of the module 30 includes webs 48 under portions of all three die attach pads 60, and additional webs 49 under a number of the connection pads 62. Those having skill in the art will appreciate that these webs 48, 49 serve to retain the various parts of the lead frame 42 in the encapsulation 44, while allowing the external surfaces of the die-attach pads 60 and connection pads 62 adjacent the webs 48, 49 to remain exposed on the mounting surface 56 and along the vertical edges of the package 38. Having the die-attach pads 60 and connection pads 62 partially exposed adjacent the webs 48, 49 in this manner, allows the size of the module 30 to be reduced in comparison to prior modules, and facilitates making electrical and thermal connections between the module 30 and traces on the circuit board 40. The reduction in size of the exemplary embodiment of the module 30 according to the invention, with respect to the prior module 10, can be seen, by comparing FIG. 8 with FIG. 1.

It should be noted that, although some of the webs 48 in the exemplary embodiment are positioned to pass directly under the dies 32, 34, 36, this need not be done in other embodiments of the invention. It may be desirable to use different configurations or placements in other embodiments of the invention, for structural purposes or to provide a desired thermal path from a die through the die attach pad 60 to a heat sink contacting the exposed portions of the external surface of the lead frame 42 adjacent the web 48.

Placing the webs 48 directly under the dice 32, 34, 36 is counterintuitive to traditional thinking of those skilled in the art relating to creating the most efficient heat transfer path under the dice for removal of heat generated by the dice. Traditional thinking would not result in placing a web 48 of thermally insulating encapsulation directly under the dice of an electronic module. The webs 48 of the present invention are relatively thin, and when placed in the bottom surface of a lead frame 42 constructed of a highly thermally conductive material like copper or aluminum, have been shown to have only a negligible effect on heat transfer, while significantly improving the robustness of the module by precluding loss of the various parts 60, 62 of the lead frame 42. The heat spreads in a horizontal direction within the lead frame 42, and is readily conducted out of the exposed areas of the external surface 52 of the lead frame adjacent the webs 48.

The invention also provides a method for attaching leadless lead frame electronic package 38 to a circuit board 40. An LLP 38 is provided, having a lead frame 42 of thermally-and-electrically conductive material encapsulated in an encapsulation 44 of electrically-insulating material to define a planar mounting surface 56 including an exposed web 48 of encapsulation forming a portion of the planar mounting surface 56. The lead frame 42 includes parallel internal and external planar surfaces 50, 52 having at least one cut-out 64 extending from the internal to the external surfaces 50, 52 to define a die-attach pad 60 and at least one connection pad 62 electrically isolated from the die-attach pad 60. The external surface of the die-attach pad defines a recessed C-shaped channel 54 therein for receiving the web 48 of encapsulation 44, with the external planar surface 52 of the die-attach pad 60 remaining exposed through the encapsulation 44 adjacent the web 48. The web 48, and the external planar surface 52 of the die-attach pad 60 adjacent the web 48, extend generally co-planar with the mounting surface 56. At least part of the exposed external surface 52 of the die-attach pad 60 adjacent the web 48 is thermally connected to the circuit board 40, preferable by a process such as soldering.

While the embodiments of the invention disclosed herein are presently considered to be preferred, various changes and modifications can be made without departing from the spirit and scope of the invention. The various elements and aspects of the invention may be used independently from one another, or in different combinations than are described above and in the drawings with regard to the exemplary embodiments.

The terms C-shaped, and L-shaped, as used herein in describing the square-cornered channels 54 and recesses 55 in the external surface 52 of the lead frame 42 are intended to include an almost limitless variety of modified or alternate shapes generally forming a C-shaped channel, and an L-shaped or J-shaped recess, having rounded or re-entrant corners, and curved or angled sides, etc.

The invention may also be utilized for LLP packages or modules not including optical components.

The scope of the invention is indicated in the appended claims. It is intended that all changes or modifications within the meaning and range of equivalents are embraced by the claims.

We claim:

1. A leadless lead frame electronic package (LLP), comprising:
a lead frame of thermally-and-electrically conductive material encapsulated in an encapsulation of electrically-insulating material to define a planar mounting surface including an exposed web of encapsulation forming a portion of the planar mounting surface;
the lead frame including parallel internal and external planar surfaces with the external surface defining a recessed C-shaped channel therein for receiving the web of encapsulation;
the external planar surface of the lead frame remaining exposed through the encapsulation adjacent the web, the web and the external planar surface adjacent the web extending generally co-planar with the mounting surface.

2. The electronic package of claim 1, including an attachment element structured to engage with an electrical component.

3. The electronic package of claim 1, further including an electrical component.

4. The electronic package of claim 1, wherein the encapsulation is a transparent material and forms a lens.

5. The electronic package of claim 4, wherein:
the internal surface of the lead frame includes an attachment site for an optical component; and
the lens is aligned with the attachment site for the optical component.

6. The electronic package of claim 5, wherein the web is disposed under the attachment site.

7. The electronic package of claim 5, further comprising an optical component attached to the internal surface of the lead frame at the attachment site.

8. The electronic package of claim 7 wherein the internal surface of the lead frame includes a second attachment site for a second optical component.

9. The electronic package of claim 8 wherein the encapsulation forms a second lens aligned with the second attachment site.

10. The electronic package of claim 9 further comprising a second optical component attached to the internal surface of the lead frame at the second attachment site.

11. The electronic package of claim 10 wherein the first optical component is a light emitting diode (LED) and the second optical component is a photodiode.

12. The electronic package of claim 1, wherein:
the lead frame includes at least one cut-out extending from the internal surface to the external surface to define a die-attach pad and at least one connection pad electrically isolated from the die-attach pad; and
the die attach pad and the connection pads extend through the encapsulation, with a portion of the external surfaces thereof exposed and generally coplanar with the encapsulation, and with a portion of the internal surfaces thereof respectively defining a die-attach surface and a bond-connection surface.

13. The electronic package of claim 12, wherein the encapsulation extends through a portion of the at least one cut-out in the lead frame.

14. The electronic package of claim 12 wherein the external surface of the die attach pad includes the recessed area containing the web of encapsulation.

15. The electronic package of claim 14 wherein the external surface of at least one of the connection pads includes a second recessed area containing a second web of encapsulation.

16. A leadless electronic module, comprising:
a lead frame of thermally-and-electrically conductive material encapsulated in an encapsulation of electrically-insulating material to define a planar mounting surface including an exposed web of encapsulation forming a portion of the planar mounting surface; the lead frame including parallel internal and external planar surfaces with the external surface defining a recessed C-shaped channel therein for receiving the web of encapsulation; the external planar surface of the lead frame remaining exposed through the encapsulation adjacent the web, the web and the external planar surface adjacent the web extending generally co-planar with the mounting surface; and
an electronic die attached to the internal planar surface of the lead frame.

17. The electronic module of claim 16, wherein:
the lead frame includes at least one cut-out extending from the internal to the external surfaces to define a die-attach pad and at least one connection pad electrically isolated from the die-attach pad;
the die attach pad and the leadless connection pads extend through the encapsulation, with a portion of the external surfaces thereof exposed and generally coplanar with the encapsulation, and with a portion of the internal surfaces thereof respectively defining a die-attach surface and a bond-connection surface; and
the die is attached to the exposed die-attach surface.

18. The electronic module of claim 16 wherein the encapsulation is a transparent material and forms a lens.

19. The electronic module of claim 18, wherein:
the internal surface of the lead frame includes an attachment site for an optical component;
the die is an optical component attached to the internal surface of the lead frame at the attachment site and the lens is aligned with the attachment site for the optical component.

20. The electronic module of claim 19 wherein:
the internal surface of the lead frame includes a second attachment site for a second optical component;
the encapsulation forms a second lens aligned with the second attachment site; and
the electronic module further comprises a second optical component attached to the internal surface of the lead frame at the second attachment site.

21. The electronic module of claim 20 wherein the first optical component is a light emitting diode (LED) and the second optical component is a photodiode, to thereby form an optical transceiver module.

22. A method for attaching a leadless lead frame electronic package (LLP) to a circuit board, the method comprising:
providing an LLP having a lead frame of thermally-and-electrically conductive material encapsulated in an encapsulation of electrically-insulating material to define a planar mounting surface including an exposed web of encapsulation forming a portion of the planar mounting surface, the lead frame including parallel internal and external planar surfaces having at least one cut-out extending from the internal to the external surfaces to define a die-attach pad and at least one connection pad electrically isolated from the die-attach pad, with the external surface of the die-attach pad defining a recessed C-shaped channel therin for receiving the web of encapsulation, the external planar surface of the die-attach pad remaining exposed through the encapsulation adjacent the web, the web and the external planar surface of the die-attach pad adjacent the web extending generally co-planar with the mounting surface; and
thermally connecting at least part of the exposed external surface of the die-attach pad adjacent the web to the circuit board.

23. The method of claim 22 further including thermally connecting the at least part of the exposed external surface of the die-attach pad adjacent the web to the circuit board with solder.
